(19) United States
(12) Patent Application Publication
(10) Pub. No.: US 2026/0196253 A1
(43) Pub. Date: Jul. 9, 2026

(54) MEMORY CELL, DATA READ-WRITE CIRCUIT, MEMORY, AND MEMORY MANUFACTURING METHOD

(71) Applicant: PEKING UNIVERSITY, Beijing (CN)

(72) Inventors: Yimao CAI, Beijing (CN); Zongwei WANG, Beijing (CN); Haisu ZHANG, Beijing (CN); Lin BAO, Beijing (CN)

(73) Assignee: PEKING UNIVERSITY, Beijing (CN)

(21) Appl. No.: 19/440,106

(22) Filed: Jan. 5, 2026

(30) Foreign Application Priority Data
Jan. 6, 2025 (CN) 202510018855.5

(51) Int. Cl. G11C 5/06; G11C 7/10

(52) U.S. Cl. CPC G11C 5/063; G11C 7/1069; G11C 7/1096

(57) ABSTRACT

A memory cell, a data read-write circuit, a memory, and a memory manufacturing method are provided. The memory cell includes: a horizontal semiconductor layer extending along a first direction, and a write bit line, a write transistor, a read transistor, and a read word line which are located on the horizontal semiconductor layer and sequentially arranged along the first direction. The write bit line and the read word line each extend along a second direction intersecting the first direction. The read transistor extends along a third direction perpendicular to the first direction and the second direction and penetrates through the horizontal semiconductor layer. A source line, the read transistor, and a read bit line are arranged along the third direction. Simultaneous photolithography of multiple layers of stacked memory cells can be supported and meanwhile an area overhead of a single layer of memory cells is reduced.

### CROSS-REFERENCE TO RELATED APPLICATION

This application claims priority under 35 U.S.C. §119 to Chinese Patent Application No. 202510018855.5, filed with CNIPA on January 06, 2025, entitled “MEMORY CELL, DATA READ-WRITE CIRCUIT, MEMORY, AND MEMORY MANUFACTURING METHOD”, the entire contents of which are incorporated herein by reference.

### TECHNICAL FIELD

The present disclosure relates to the field of integrated circuit design and manufacturing technologies, and in particular, to a memory cell, a data read-write circuit, a memory, and a memory manufacturing method.

### BACKGROUND

With continuous development of the integrated circuit manufacturing process, the market has set higher and higher requirements for the capacity, the manufacturing cost, and the data transmission rate of storage product. Three-dimensional stacked storage structure becomes an important development direction.

Two-dimensional memory arrays pose relatively large challenges to the process and manufacture of devices in terms of miniaturization. Stacking multiple two-dimensional memory cell arrays in a vertical direction becomes a technological development direction to realize high-density storage.

### SUMMARY

In view of the above, the present disclosure provides a memory cell, a data read-write circuit, a memory, and a memory manufacturing method, which at least can support simultaneous photolithography of multiple layers of stacked memory cells while reducing an area overhead of a single layer of memory cells, and can reduce a volume of a manufactured product without any decrease in memory capacity, so as to reduce process complexity and cost of the manufactured product.

According to various embodiments of the present disclosure, in a first aspect, there is provided a memory cell, including: a source line, a read bit line, a write word line, a horizontal semiconductor layer extending along a first direction, and a write bit line, a write transistor, a read transistor, and a read word line which are located on the horizontal semiconductor layer and sequentially arranged along the first direction. The write bit line and the read word line both extend along a second direction intersecting the first direction. The read transistor extends along a third direction perpendicular to both the first direction and the second direction and penetrates through the horizontal semiconductor layer. The read transistor includes a vertical gate dielectric layer and a vertical semiconductor layer that extends along the third direction, and the vertical gate dielectric layer is located between the vertical semiconductor layer and the horizontal semiconductor layer. The write transistor extends along the first direction and surrounds a part of the horizontal semiconductor layer. The horizontal semiconductor layer and the write word line are arranged along the second direction. The source line, the read transistor, and the read bit line are arranged along the third direction.

In the memory cell according to the above embodiment, the write transistor extends along the first direction and surrounds a part of the horizontal semiconductor layer; the read transistor extends along the third direction and penetrates through the horizontal semiconductor layer; the write bit line, the write transistor, the read transistor, and the read word line are sequentially arranged along the first direction; the horizontal semiconductor layer and the write word line are arranged along the second direction; and the source line, the read transistor, and the read bit line are arranged along the third direction. Two control gates are formed by using a part of the vertical gate dielectric layer, the vertical semiconductor layer, and a part of the vertical gate dielectric layer which are arranged in sequence along the first direction, so that volumes of the two control gates are effectively reduced, the memory cells adjacent along the second direction in the same memory cell array can be conveniently configured to share the write bit line and the read word line, and the memory cells adjacent along the third direction in the same memory cell array can be conveniently configured to share the write word line, thereby supporting simultaneous photolithography of the multiple layers of stacked memory cells, and reducing the process complexity and cost of the manufactured product. In addition, since one of the two control gates is connected to one end of the write transistor to form a storage node, and the other control gate is connected to the read word line to read data, an area occupied by capacitors is relatively reduced, thereby reducing the area overhead of the single layer of memory cells, and reducing the volume of the manufactured product without any decrease in memory capacity.

According to some embodiments, the vertical gate dielectric layer extends along the third direction and circumferentially surrounds the vertical semiconductor layer, so as to form the annular vertical gate dielectric layer extending along a direction perpendicular to a substrate. The vertical semiconductor layer surrounded by the vertical gate dielectric layer is used as a common vertical semiconductor layer for the two gates, thereby effectively reducing the volumes of the two control gates, and reducing the process complexity and cost of the manufactured product. In addition, since one of the two control gates is connected to one end of the write transistor to form the storage node, and the other control gate is connected to the read word line to read data, the area occupied by capacitors is relatively reduced, thereby reducing the area overhead of the single layer of memory cells, and reducing the volume of the manufactured product without any decrease in memory capacity.

According to some embodiments, the write transistor includes a gate-all-around dielectric layer, a first source/drain contact region, and a second source/drain contact region. The gate-all-around dielectric layer extends along the first direction and circumferentially surrounds a part of the horizontal semiconductor layer. The write word line extends along the third direction and is located on a side of the gate-all-around dielectric layer away from the horizontal semiconductor layer along the second direction. The first source/drain contact region is located at the horizontal semiconductor layer between the write bit line and the gate-all-around dielectric layer. The second source/drain contact region is located at the horizontal semiconductor layer between the gate-all-around dielectric layer and the read transistor. Since the write transistor includes the first source/drain contact region, the horizontal semiconductor layer, and the second source/drain contact region which are sequentially arranged along the first direction, the gate-all-around dielectric layer which extends along the first direction and circumferentially surrounds a part of the horizontal semiconductor layer can be conveniently formed to manufacture a gate-all-around transistor with a horizontal channel, and the write word lines of the memory cells adjacent along the direction perpendicular to the substrate can be conveniently manufactured simultaneously in the same process step, thus reducing the complexity and cost of the manufacturing process.

According to some embodiments, the write transistor further includes a gate-all-around electrode layer, the gate-all-around electrode layer being located between the write word line and the gate-all-around dielectric layer and circumferentially surrounding the gate-all-around dielectric layer. Hence, the gate-all-around electrode layers of the memory cells adjacent along the direction perpendicular to the substrate can be conveniently manufactured simultaneously in the same process step, and the write word lines of the memory cells adjacent along the direction perpendicular to the substrate can be conveniently manufactured simultaneously in the same process step, thus reducing the complexity and cost of the manufacturing process.

According to some embodiments, the read transistor includes a first source/drain contact region and a second source/drain contact region. The first source/drain contact region is located at the vertical semiconductor layer between the horizontal semiconductor layer and the read bit line. The second source/drain contact region is located at the vertical semiconductor layer between the horizontal semiconductor layer and the source line. Hence, a gate-all-around transistor with a vertical channel can be conveniently manufactured, simultaneous photolithography of multiple layers of stacked memory cells can be supported, and both the vertical semiconductor layers and the vertical gate dielectric layers of the memory cells adjacent along the direction perpendicular to the substrate can be conveniently manufactured simultaneously in same process steps, thus reducing the complexity and cost of the manufacturing process.

According to various embodiments of the present disclosure, in a second aspect, there is provided a memory, including at least one layer of memory array. One memory array includes multiple memory cells according to any one of the previous embodiments, these memory cells being arranged in an array with the first direction as a row direction and the second direction as a column direction. The at least one memory array is arranged along the third direction. The memory cells adjacent in the first direction share the read word line extending in the second direction, and share the write bit line extending in the second direction. The memory cells adjacent along the third direction share the write word line extending along the third direction. In this way, simultaneous photolithography of multiple layers of stacked memory cells can be supported, and both the vertical semiconductor layers and the vertical gate dielectric layers of the memory cells adjacent along the direction perpendicular to the substrate can be conveniently manufactured simultaneously in same process steps, thus reducing the complexity and cost of the manufacturing process.

According to various embodiments of the present disclosure, in a third aspect, there is provided a data read-write circuit, including a write transistor and a read transistor. The write transistor is configured as follows: a first end of the write transistor is connected to a write bit line, and a control end of the write transistor is connected to a write word line. The read transistor is configured as follows: a first control end of the read transistor is connected to a second end of the write transistor, a second control end of the read transistor is connected to a read word line, a first end of the read transistor is connected to a read bit line, and a second end of the read transistor is connected to a source line. The read transistor is a gate-all-around transistor with a vertical channel. The read transistor includes a vertical gate dielectric layer and a vertical semiconductor layer that extends along a direction perpendicular to a substrate. The vertical gate dielectric layer surrounds an outer side wall of the vertical semiconductor layer, and the vertical gate dielectric layer is located between the vertical semiconductor layer and a horizontal semiconductor layer. The second end of the write transistor is connected to the first control end of the read transistor to form a storage node, the second control end of the read transistor is connected to the read word line, the first end of the read transistor is connected to the read bit line, and the second end of the read transistor is connected to the source line; with the above arrangements, data is written into the storage node through the write bit line in a case that the write transistor is controlled to be turned on through the write word line, and data is read from the storage node through the read bit line in a case that the read transistor is controlled to be turned on through the read word line. An area occupied by capacitors is relatively reduced, thereby reducing the area overhead of the single layer of memory cells, and reducing the volume of the manufactured product without any decrease in memory capacity.

According to various embodiments of the present disclosure, in a fourth aspect, there is provided a three-dimensional data read-write circuit, including at least one layer of circuit array. One layer of circuit array includes multiple data read-write circuits according to any one of the previous embodiments, these data read-write circuits being arranged in an array with a first direction as a row direction and a second direction as a column direction. The at least one circuit array is arranged along a third direction. The data read-write circuits adjacent along the first direction share the read word line and the write bit line. The data read-write circuits adjacent along the third direction share the write word line. The read transistor is a gate-all-around transistor with a vertical channel. The read transistor includes a vertical gate dielectric layer and a vertical semiconductor layer that extends along a direction perpendicular to a substrate. The vertical gate dielectric layer surrounds an outer side wall of the vertical semiconductor layer, and the vertical gate dielectric layer is located between the vertical semiconductor layer and a horizontal semiconductor layer. Therefore, simultaneous photolithography of multiple layers of stacked memory cells can be supported, and the process complexity and cost of the manufactured product are reduced. In addition, since one of two control gates is connected to one end of the write transistor to form a storage node, and the other control gate is connected to the read word line to read data, an area occupied by capacitors is relatively reduced, thereby reducing the area overhead of the single layer of memory cells, and reducing the volume of the manufactured product without any decrease in memory capacity.

According to various embodiments of the present disclosure, in a fifth aspect, there is provided a memory manufacturing method, including: providing a substrate, where the substrate is provided with a stack, the stack includes sacrificial layers and semiconductor material layers which are sequentially and alternately stacked along a direction away from the substrate, and multiple first grooves are arranged in the stack, which are arranged in an array with a first direction as a row direction and a second direction as a column direction, where a part of the substrate is exposed through each first groove; forming an isolation layer which fills the first grooves and covers a top surface of a top semiconductor material layer of the stack; forming a first through hole in the stack, where a part of the substrate and a part of the semiconductor material layers are exposed through the first through hole, and the first through hole is configured to define a write transistor; forming the write transistor surrounding a part of the semiconductor material layer in each semiconductor material layer through the first through hole, and then forming a write word line filling the first through hole; forming a second groove in the stack, where a part of the substrate is exposed through the second groove, and the second groove is configured to define a read transistor; and forming a vertical gate dielectric layer on an inner side wall of the second groove, and then forming a vertical semiconductor layer filling the second groove; where a part of the semiconductor material layer, extending along the second direction, is configured to form a write bit line, a part of the semiconductor material layer, extending along the second direction, is configured to form a read word line, and the vertical gate dielectric layer and the vertical semiconductor layer are configured to jointly form the read transistor, so as to obtain the write bit line, the write transistor, the read transistor, and the read word line which are sequentially arranged along the first direction; a part of the semiconductor material layer, extending along the first direction, is configured to form a horizontal semiconductor layer; and the first direction intersect with the second direction.

In the memory manufacturing method according to the above embodiment, the stack including the sacrificial layers and the semiconductor material layers which are sequentially and alternately stacked in the direction away from the substrate is formed on the substrate, and the multiple first grooves which are arranged in an array with the first direction as the row direction and the second direction as the column direction and each expose a part of the substrate are formed in the stack, thereby preliminarily defining parameters such as the shape, the size, and the position of each memory cell in a subsequently manufactured memory cell array. The first through hole exposing a part of the substrate and a part of the semiconductor material layers is formed in the stack, and the first through hole is configured to define the write transistor, thereby defining parameters such as the shape, the size, and the position of the write transistor of each memory cell in the subsequently manufactured memory cell array. The write transistor surrounding a part of the semiconductor material layer is formed in each semiconductor material layer through the first through hole, and then, the write word line filling the first through hole is formed, thereby simultaneously manufacturing the write word line shared by the memory cells adjacent along a direction perpendicular to the substrate in the same process step. The second groove exposing a part of the substrate is formed in the stack, and the second groove is configured to define the read transistor, thereby defining parameters such as the shape, the size, and the position of the read transistor of each memory cell in the subsequently manufactured memory cell array. The vertical gate dielectric layer is formed on the inner side wall of the second groove, the vertical semiconductor layer filling the second groove is then formed, a part of the semiconductor material layer extending along the second direction is configured to form the write bit line, a part of the semiconductor material layer extending along the second direction is configured to form the read word line, and the vertical gate dielectric layer and the vertical semiconductor layer are configured to jointly form the read transistor, so as to obtain the write bit line, the write transistor, the read transistor, and the read word line which are sequentially arranged along the first direction. An area occupied by capacitors is relatively reduced, thereby reducing the area overhead of the single layer of memory cells, and reducing the volume of the manufactured product without any decrease in memory capacity.

According to some embodiments, an etch stop layer is arranged between the substrate and the stack; and the stack is etched based on the etch stop layer, to form at least one of the first grooves, the first through hole, or the second groove. Hence, unnecessary etch damage to the substrate is avoided in the process of etching any one of the first grooves, the first through hole, and the second groove, and the yield, the performance, and the reliability of the manufactured product are improved.

### BRIEF DESCRIPTION OF THE DRAWINGS

In order to illustrate the technical solutions in the embodiments of the present disclosure more clearly, the drawings required for describing the embodiments will be described briefly. Apparently, the following described drawings are merely for some embodiments of the present disclosure, and other drawings can be derived from the drawings by those of ordinary skill in the art without any creative effort.

FIG. 1 is a schematic top view of a memory cell according to some embodiments of the present disclosure;

FIG. 2 is a schematic longitudinal sectional view of FIG. 1 along the X-axis;

FIG. 3 is a schematic longitudinal sectional view of FIG. 1 along the Y-axis;

FIG. 4 is a schematic top view of a memory according to some embodiments of the present disclosure;

FIG. 5 is a schematic longitudinal sectional view of FIG. 4 along the X-axis;

FIG. 6 is a schematic longitudinal sectional view of FIG. 4 along the Y-axis;

FIG. 7 is a schematic flowchart of a memory manufacturing method according to some embodiments of the present disclosure;

FIG. 8 is a schematic top view of a structure obtained after a stack is formed in step S10 in the memory manufacturing method according to some embodiments of the present disclosure;

FIG. 9 is a schematic longitudinal sectional view of FIG. 8 along the X-axis;

FIG. 10 is a schematic longitudinal sectional view of FIG. 8 along the Y-axis;

FIG. 11 is a schematic top view of a structure obtained after first grooves are formed in step S10 in the memory manufacturing method according to some embodiments of the present disclosure;

FIG. 12 is a schematic longitudinal sectional view of FIG. 11 along the X-axis;

FIG. 13 is a schematic longitudinal sectional view of FIG. 11 along the Y-axis;

FIG. 14 is a schematic top view of a structure obtained after an isolation layer is formed in step S20 in the memory manufacturing method according to some embodiments of the present disclosure;

FIG. 15 is a schematic longitudinal sectional view of FIG. 14 along the X-axis;

FIG. 16 is a schematic longitudinal sectional view of FIG. 14 along the Y-axis;

FIG. 17 is a schematic top view of a structure obtained after a first through hole is formed in step S30 in the memory manufacturing method according to some embodiments of the present disclosure;

FIG. 18 is a schematic longitudinal sectional view of FIG. 17 along the X-axis;

FIG. 19 is a schematic longitudinal sectional view of FIG. 17 along the Y-axis;

FIG. 20 is a schematic top view of a structure obtained after a write word line is formed in step S40 in the memory manufacturing method according to some embodiments of the present disclosure;

FIG. 21 is a schematic longitudinal sectional view of FIG. 20 along the X-axis;

FIG. 22 is a schematic longitudinal sectional view of FIG. 20 along the Y-axis;

FIG. 23 is a schematic top view of a structure obtained after a second groove is formed in step S50 in the memory manufacturing method according to some embodiments of the present disclosure; where reference may be made to FIG. 22 for a schematic longitudinal sectional view of FIG. 23 along the Y-axis;

FIG. 24 is a schematic longitudinal sectional view of FIG. 23 along the X-axis;

FIG. 25 is a schematic top view of a structure obtained after a read transistor is formed in step S60 in the memory manufacturing method according to some embodiments of the present disclosure; where reference may be made to FIG. 22 for a schematic longitudinal sectional view of FIG. 25 along the Y-axis;

FIG. 26 is a schematic longitudinal sectional view of FIG. 25 along the X-axis;

FIG. 27 is a schematic circuit diagram of a data read-write circuit according to some embodiments of the present disclosure; and

FIG. 28 is a schematic circuit diagram of a three-dimensional data read-write circuit according to some embodiments of the present disclosure.

Reference signs are explained as follows:

100: memory cell; 10: substrate; 11: source line; 12: read bit line; 13: write word line; 14: write bit line; 15: write transistor; 16: read transistor; 161: vertical gate dielectric layer; 162: vertical semiconductor layer; 17: read word line; 20: horizontal semiconductor layer; 151: gate-all-around dielectric layer; 152: gate-all-around electrode layer; S1/D1: first source/drain contact region; S2/D2: second source/drain contact region; 200: memory; 300: data read-write circuit; 400: three-dimensional data read-write circuit; 30: stack; 31: sacrificial layer; 32: semiconductor material layer; 41: first groove; 32T: top semiconductor material layer; 42: isolation layer; 43: first through hole; 44: second groove; 45: etch stop layer.

### DETAILED DESCRIPTION

To facilitate an understanding of the present disclosure, the present disclosure is described more fully hereinafter with reference to the accompanying drawings. Preferred embodiments of the present disclosure are shown in the drawings. However, the present disclosure may be implemented in many different forms and is not limited to the embodiments set forth herein. Rather, these embodiments are provided to make the disclosure of the present disclosure more thorough and complete.

Unless defined otherwise, all technical and scientific terms used herein have the same meanings as would generally understood by those skilled in the technical field of the present disclosure. The terms used herein in the specification of the present disclosure are for the purpose of describing specific embodiments only, and are not intended to limit the present disclosure.

It should be understood that when an element or layer is referred to as being "on", "adjacent to", "connected to", or "coupled to" another element or layer, it can be directly on, adjacent, connected, or coupled to the other element or layer, or intervening elements or layers may be present. In contrast, when an element is referred to as being "directly on", "directly adjacent to", "directly connected to", or "directly coupled to" another element or layer, no intervening elements or layers are present. It should be understood that, although the terms "first", "second", "third", etc. may be used to describe various elements, components, regions, layers, doping types and/or parts, these elements, components, regions, layers, doping types and/or parts should not be limited by these terms. These terms are only used to distinguish one element, component, region, layer, doping type or part from another element, component, region, layer, doping type or part. Therefore, a first element, component, region, layer, doping type or part discussed below could be termed a second element, component, region, layer or part without departing from the teaching of the present invention. For example, a first doping type may be termed a second doping type, and similarly, a second doping type may be termed a first doping type. The first doping type and the second doping type are different doping types, for example, the first doping type may be P-type and the second doping type may be N-type, or the first doping type may be N-type and the second doping type may be P-type.

Spatially relative terms such as "under", "below", "beneath", "above", and "over" may be used herein to describe one element or feature's relationship to another element or feature as illustrated in the drawings. It should be understood that the spatially relative terms also encompass different orientations of a device in use or operation in addition to the orientation depicted in the drawings. For example, if the device in the drawings is turned over, elements or features described as "below" or "under" or "beneath" other elements or features would then be oriented "above" the other elements or features. Therefore, the exemplary terms "below" and "under" can encompass both orientations of "above" and "below". In addition, the device may have additional orientations (e.g., be rotated by 90 degrees or have other orientations) and the spatial descriptors used herein are interpreted correspondingly.

As used herein, the singular forms "a", "an", and "the" may include the plural forms as well, unless the context clearly indicates otherwise. It should be further understood that the terms "include" and/or "comprise", when used in this specification, specify the presence of stated feature(s), integer(s), step(s), operation(s), element(s), and/or component(s), but do not preclude the presence or addition of one or more other features, integers, steps, operations, elements, components, and/or groups. Meanwhile, as used herein, the term "and/or" includes any and all combinations of the associated listed items.

It should be noted that the illustrations provided in the embodiments are only for illustrating the basic idea of the present disclosure, the illustrations only show the components related to the present disclosure and are not drawn according to the number, shape and size of the components in actual implementation, the form, number and proportion of each component in actual implementation may be changed arbitrarily, and the component layout may be more complicated.

It should be noted that the mutual insulation between two parts in the embodiments of the present disclosure includes, but is not limited to, the presence of at least one of an insulating material, an insulating gas, or a gap between the two parts. The direction perpendicular to the substrate in the embodiments of the present disclosure may be a direction perpendicular to a surface of the substrate, for example, a top surface, and the direction parallel to the substrate may be a direction parallel to the surface of the substrate, for example, the top surface.

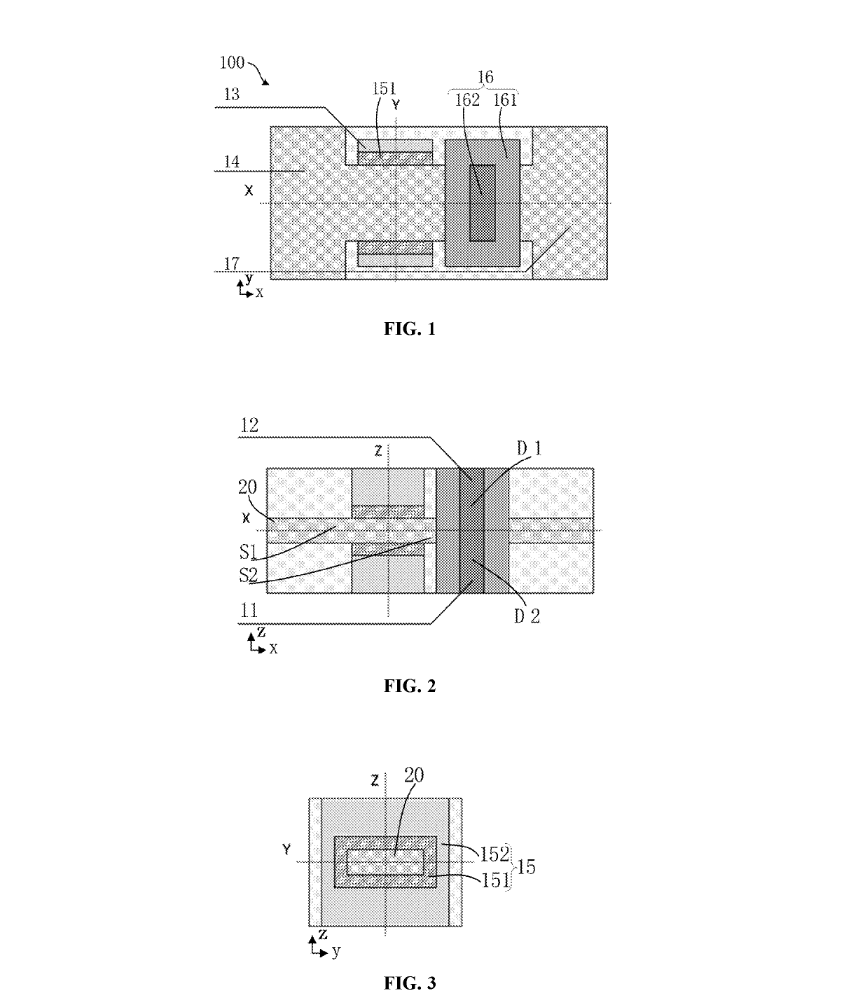

Referring to FIG. 1 to FIG. 3, in some embodiments, there is provided a memory cell 100, including: a source line 11, a read bit line 12, a write word line 13, a horizontal semiconductor layer 20 extending along a first direction, and a write bit line 14, a write transistor 15, a read transistor 16 and a read word line 17 which are located on the horizontal semiconductor layer 20 and sequentially arranged along the first direction. The write bit line 14 and the read word line 17 both extend along a second direction intersecting the first direction. The read transistor 16 extends along a third direction perpendicular to both the first direction and the second direction, and penetrates through the horizontal semiconductor layer 20. The read transistor 16 includes a vertical gate dielectric layer 161 and a vertical semiconductor layer 162 that extends along the third direction. The vertical gate dielectric layer 161 is located between the vertical semiconductor layer 162 and the horizontal semiconductor layer 20. The write transistor 15 extends along the first direction and surrounds a part of the horizontal semiconductor layer 20. The horizontal semiconductor layer 20 and the write word line 13 are arranged along the second direction. The source line 11, the read transistor 16, and the read bit line 12 are arranged along the third direction.

Exemplarily, in the memory cell 100 according to the above embodiment, the write transistor 15 extends along the first direction and surrounds a part of the horizontal semiconductor layer 20; the read transistor 16 extends along the third direction and penetrates through the horizontal semiconductor layer 20; the write bit line 14, the write transistor 15, the read transistor 16, and the read word line 17 are sequentially arranged along the first direction; the horizontal semiconductor layer 20 and the write word line 13 are arranged along the second direction; and the source line 11, the read transistor 16, and the read bit line 12 are arranged along the third direction. Two control gates are formed by using a part of the vertical gate dielectric layer 161, the vertical semiconductor layer 162, and a part of the vertical gate dielectric layer 161 which are arranged in sequence along the first direction, so that volumes of the two control gates are effectively reduced. Accordingly, memory cells 100 adjacent along the second direction in an array of memory cells 100 at a same layer can be conveniently configured to share the write bit line 14 and the read word line 17, and memory cells 100 adjacent along the third direction can be conveniently configured to share the write word line 13, thereby supporting simultaneous photolithography of multiple layers of stacked memory cells 100, and reducing process complexity and cost of product manufacturing. In addition, since one of the two control gates is connected to one end of the write transistor 15 to form a storage node, and the other control gate is connected to the read word line 17 to read data, an area occupied by a capacitor is relatively reduced, thereby reducing an area overhead of a single layer of memory cells 100; as a result, a volume of the manufactured product can be reduced without any decrease in the memory capacity.

Still referring to FIG. 1 to FIG. 3, in some embodiments, the vertical gate dielectric layer 161 extends along the third direction and circumferentially surrounds the vertical semiconductor layer 162, so as to form an annular vertical gate dielectric layer 161 extending along a direction perpendicular to a substrate 10. The vertical semiconductor layer 162 surrounded by the vertical gate dielectric layer 161 is used as a common vertical semiconductor layer 162 for the two gates, thereby effectively reducing the volumes of the two control gates, and reducing the process complexity and cost of product manufacturing. In addition, since one of the two control gates is connected to one end of the write transistor 15 to form the storage node, and the other control gate is connected to the read word line 17 to read data, the area occupied by the capacitor is relatively reduced, thereby reducing the area overhead of the single layer of memory cells 100, and reducing the volume of the manufactured product without any decrease in the memory capacity.

Still referring to FIG. 1 to FIG. 3, in some embodiments, the write transistor 15 includes a gate-all-around dielectric layer 151, a first source/drain contact region S1, and a second source/drain contact region S2. The gate-all-around dielectric layer 151 extends along the first direction and circumferentially surrounds a part of the horizontal semiconductor layer 20. The write word line 13 extends along the third direction and is located on a side of the gate-all-around dielectric layer 151 away from the horizontal semiconductor layer 20 along the second direction. The first source/drain contact region S1 is located at the horizontal semiconductor layer 20 between the write bit line 14 and the gate-all-around dielectric layer 151. The second source/drain contact region S2 is located at the horizontal semiconductor layer 20 between the gate-all-around dielectric layer 151 and the read transistor 16. Since the write transistor 15 includes the first source/drain contact region S1, the horizontal semiconductor layer 20, and the second source/drain contact region S2 which are sequentially arranged along the first direction, the gate-all-around dielectric layer 151 which extends along the first direction and circumferentially surrounds a part of the horizontal semiconductor layer 20 can be conveniently formed to manufacture a gate-all-around transistor with a horizontal channel, and the write word lines 13 of the memory cells 100 adjacent along the direction perpendicular to the substrate 10 can be conveniently manufactured simultaneously in the same process step, thus reducing the complexity and cost of a manufacturing process.

Still referring to FIG. 1 to FIG. 3, in some embodiments, the write transistor 15 further includes a gate-all-around electrode layer 152, the gate-all-around electrode layer 152 being located between the write word line 13 and the gate-all-around dielectric layer 151 and circumferentially surrounding the gate-all-around dielectric layer 151, so that the gate-all-around electrode layers 152 of the memory cells 100 adjacent along the direction perpendicular to the substrate 10 can be conveniently manufactured simultaneously in the same process step, and the write word lines 13 of the memory cells 100 adjacent along the direction perpendicular to the substrate 10 can be conveniently manufactured simultaneously in the same process step, thus reducing the complexity and cost of the manufacturing process.

Still referring to FIG. 1 to FIG. 3, in some embodiments, the read transistor 16 includes a first source/drain contact region D1 and a second source/drain contact region D2. The first source/drain contact region D1 is located at the vertical semiconductor layer 162 between the horizontal semiconductor layer 20 and the read bit line 12. The second source/drain contact region D2 is located at the vertical semiconductor layer 162 between the horizontal semiconductor layer 20 and the source line 11. In this way, a gate-all-around transistor with a vertical channel can be conveniently manufactured, simultaneous photolithography of multiple layers of stacked memory cells 100 can be supported, and the vertical semiconductor layers 162 and the vertical gate dielectric layers 161 of the memory cells 100 adjacent along the direction perpendicular to the substrate 10 can be conveniently manufactured simultaneously in the same process step, thus reducing the complexity and cost of the manufacturing process.

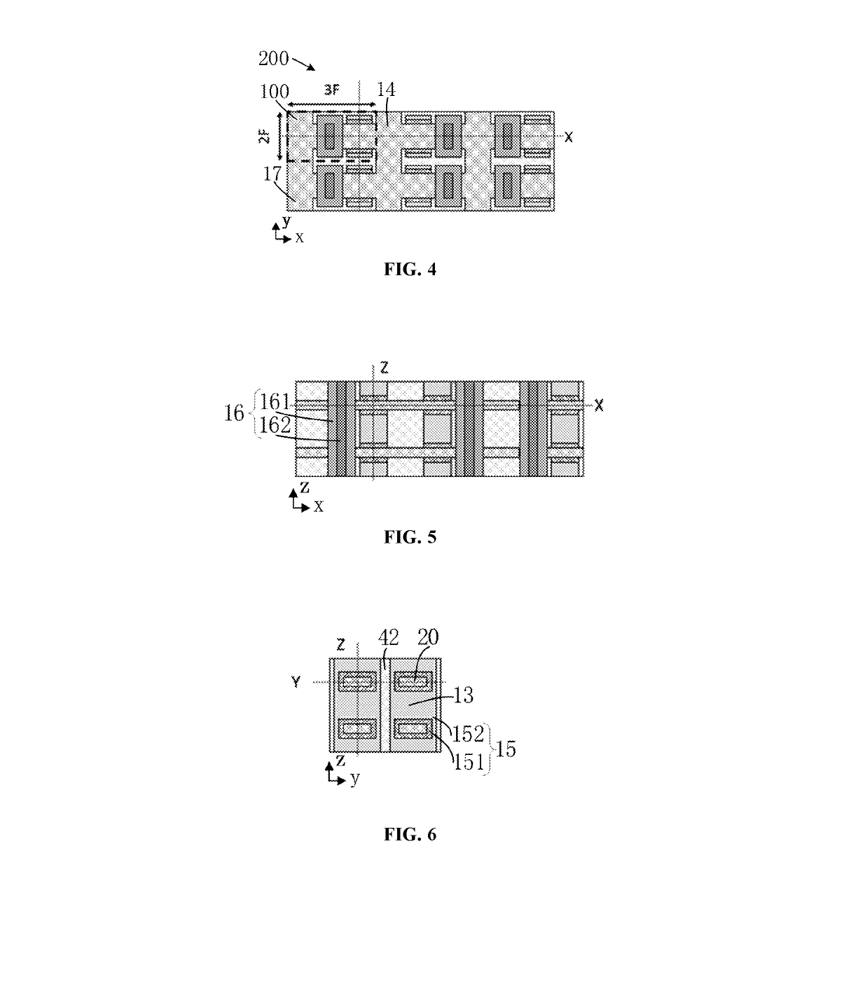

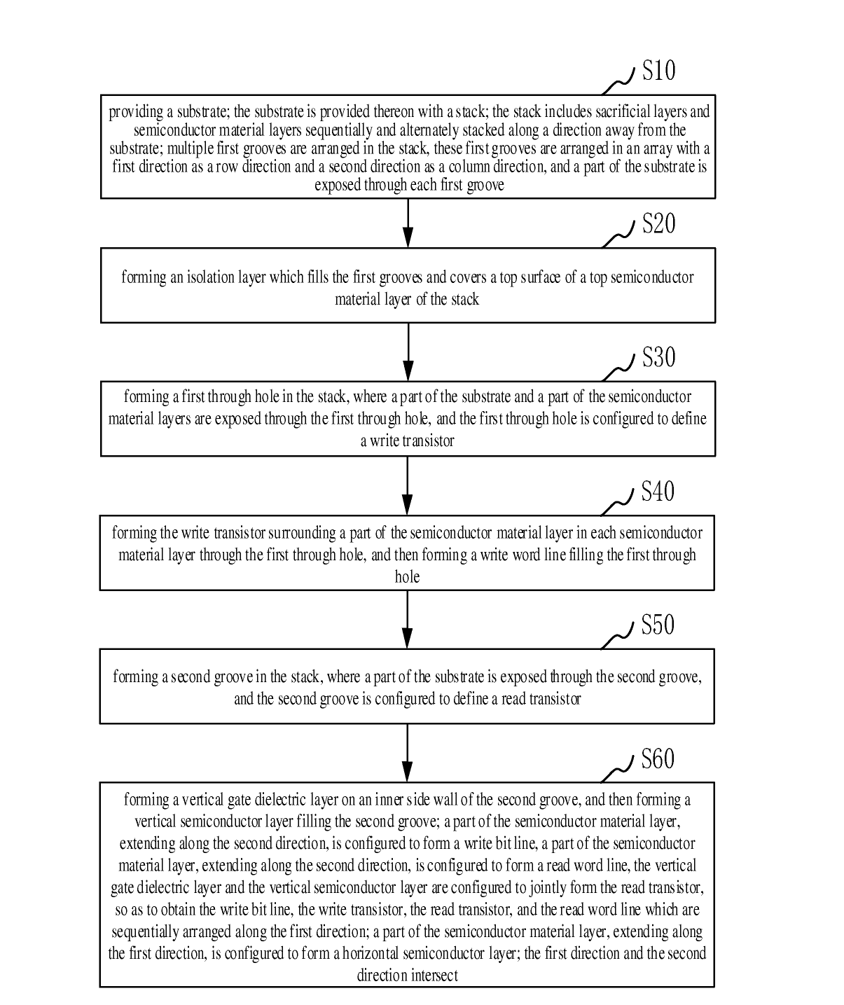

Referring to FIG. 4 to FIG. 6, in some embodiments, there is provided a memory 200, including at least one layer of memory array. Each of the at least one layer of memory array includes multiple memory cells 100 according to any one of foregoing embodiments, the multiple memory cells being arranged in an array with the first direction as a row direction and the second direction as a column direction. Optionally, the memory 200 includes multiple layers of memory arrays, and the multiple layers of memory arrays are arranged along the third direction. Memory cells 100 adjacent in the first direction share the read word line 17 extending in the second direction, and share the write bit line 14 extending in the second direction. Memory cells 100 adjacent along the third direction share the write word line 13 extending along the third direction, so that simultaneous photolithography of multiple layers of stacked memory cells 100 can be supported, and the vertical semiconductor layers 162 and the vertical gate dielectric layers 161 of the memory cells 100 adjacent along the direction perpendicular to the substrate 10 can be conveniently manufactured simultaneously in the same process step, thus reducing the complexity and cost of the manufacturing process.

Referring to FIG. 7, in some embodiments, there is provided a memory manufacturing method, including steps S10 to S60.

Step S10 includes: providing a substrate. The substrate is provided thereon with a stack. The stack includes sacrificial layers and semiconductor material layers which are sequentially and alternately stacked along a direction away from the substrate. Multiple first grooves are arranged in the stack, these first grooves are arranged in an array with a first direction as a row direction and a second direction as a column direction, and a part of the substrate is exposed through each first groove.

Step S20 includes: forming an isolation layer which fills the first grooves and covers a top surface of a top semiconductor material layer of the stack.

Step S30 includes: forming a first through hole in the stack, where a part of the substrate and a part of the semiconductor material layers are exposed through the first through hole, and the first through hole is configured to define a write transistor.

Step S40 includes: forming the write transistor surrounding a part of the semiconductor material layer in each semiconductor material layer through the first through hole, and then forming a write word line filling the first through hole.

Step S50 includes: forming a second groove in the stack, where a part of the substrate is exposed through the second groove, and the second groove is configured to define a read transistor.

Step S60 includes: forming a vertical gate dielectric layer on an inner side wall of the second groove, and then forming a vertical semiconductor layer filling the second groove. A part of the semiconductor material layer, extending along the second direction, is configured to form a write bit line. A part of the semiconductor material layer, extending along the second direction, is configured to form a read word line. The vertical gate dielectric layer and the vertical semiconductor layer are configured to jointly form the read transistor. In this way, the write bit line, the write transistor, the read transistor, and the read word line which are sequentially arranged along the first direction can be obtained. A part of the semiconductor material layer, extending along the first direction, is configured to form a horizontal semiconductor layer. The first direction and the second direction intersect.

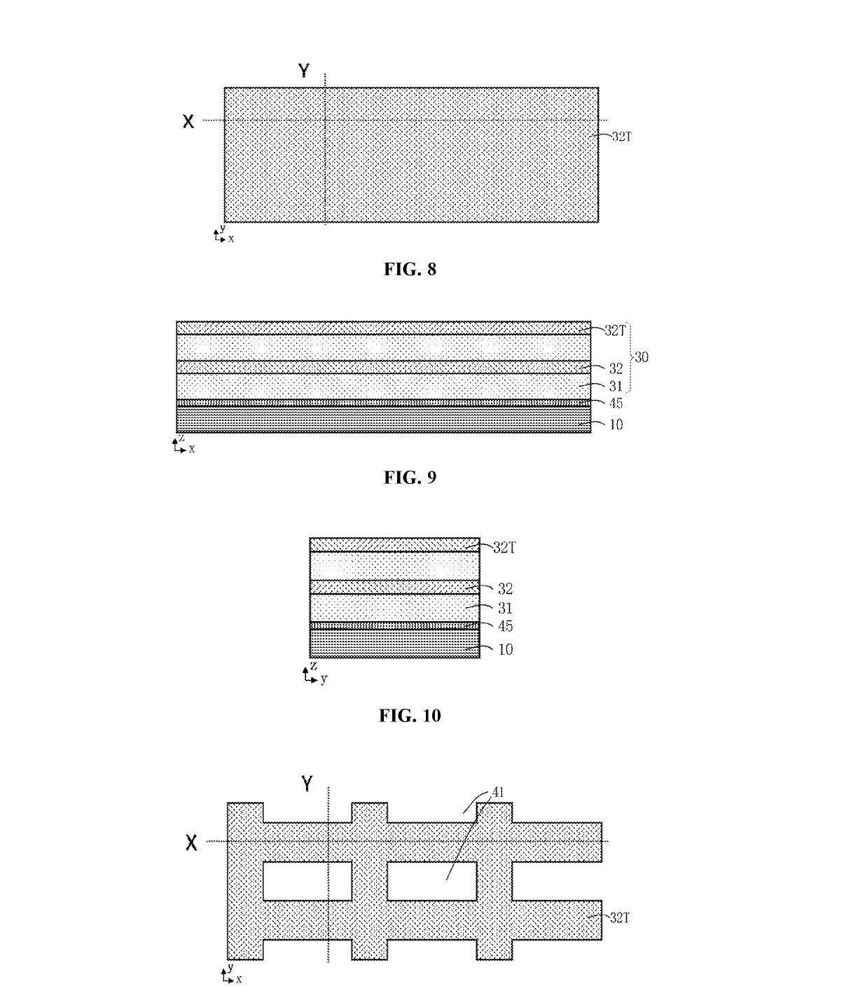

Referring to FIG. 8 to FIG. 10, in some embodiments, the substrate 10 provided in the step S10 may be made of a semiconductor material, an insulating material, a conductor material, or any combination thereof. The substrate 10 may have a single-layer structure or a multi-layer structure. For example, the substrate 10 may be a silicon (Si) substrate, a silicon germanium (SiGe) substrate, a silicon germanium carbon (SiGeC) substrate, a silicon carbide (SiC) substrate, a gallium arsenide (GaAs) substrate, an indium arsenide (InAs) substrate, an indium phosphide (InP) substrate, or other III/V semiconductor substrates or II/VI semiconductor substrates. Alternatively, further for example, the substrate 10 may be a layered substrate including, for example, Si/SiGe, Si/SiC, silicon-on-insulator (SOI), or SiGe-on-insulator. Therefore, the type of the substrate 10 should not limit the protection scope of the present disclosure.

The substrate may alternatively be other structures with a support function, such as peripheral circuits. The multiple arrays in the application may be arranged on a support structure formed by the peripheral circuits, and the support structure may be understood as the substrate.

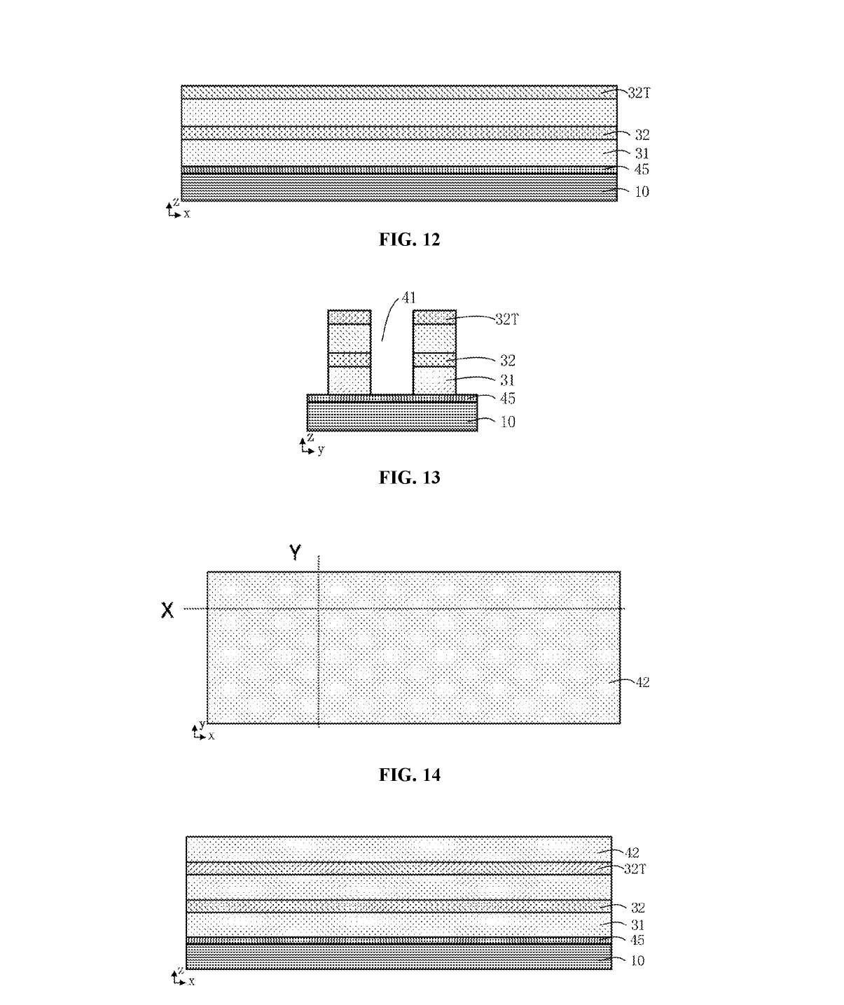

Further, with reference to FIG. 8 to FIG. 13, in some embodiments, the substrate 10 is provided thereon with a stack 30. The stack 30 includes sacrificial layers 31 and semiconductor material layers 32 which are sequentially and alternately stacked along a direction away from the substrate 10 (e.g., z-axis direction). Multiple first grooves 41 are arranged in the stack 30, these first grooves 41 are arranged in an array with a first direction (e.g.,x direction or X-axis direction) as a row direction and a second direction (e.g., y direction or Y-axis direction) as a column direction, and a part of the substrate 10 is exposed through each first groove 41.

Still referring to FIG. 8 to FIG. 13, in some embodiments, the sacrificial layer 31 may be formed on a top surface of the substrate 10 by using a deposition process and/or a spin on glass coating (SOG) process. Then, the semiconductor material layer 32 is formed on the sacrificial layer 31 by using a deposition process.

Exemplarily, a material of the sacrificial layer 31 may include: silicon oxide, silicon nitride (SiNₓ), aluminum oxide (AlOₓ), silicon carbide (SiC), or the like. For example, the material of the sacrificial layer 31 may include silicon oxide.

Exemplarily, the semiconductor material layer 32 may be made of silicon germanium (SiGe).

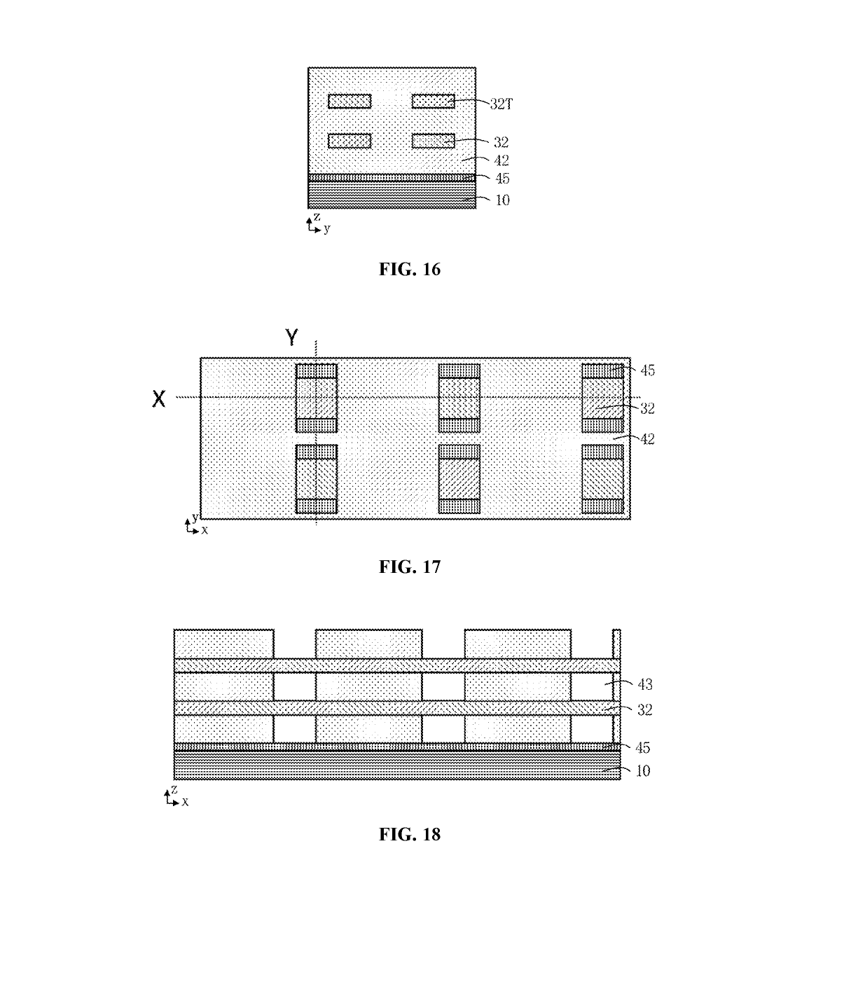

Referring to FIG. 14 to FIG. 16, in some embodiments, an isolation layer 42 which fills the first grooves 41 and covers a top surface of a top semiconductor material layer 32T of the stack 30 may be formed by using a deposition process. A material of the isolation layer 42 may include at least one of silicon nitride, silicon oxynitride, silicon carbonitride, or the like.

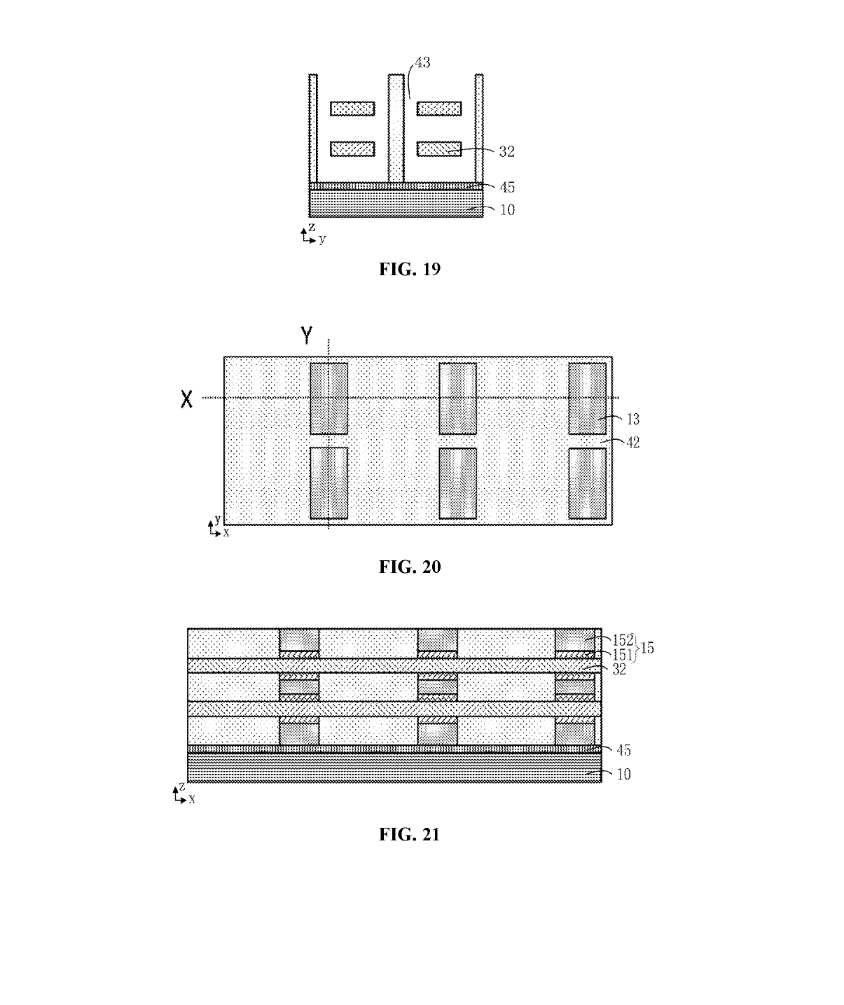

Referring to FIG. 17 to FIG. 19, in some embodiments, a first through hole 43 may be formed in the stack 30 by using an etching process, where a part of the substrate 10 and a part of the semiconductor material layers 32 are exposed through the first through hole 43. The first through hole 43 is configured to define write transistors. Horizontal semiconductor layers, which are utilized to form the write transistors, are exposed through the first through hole 43.

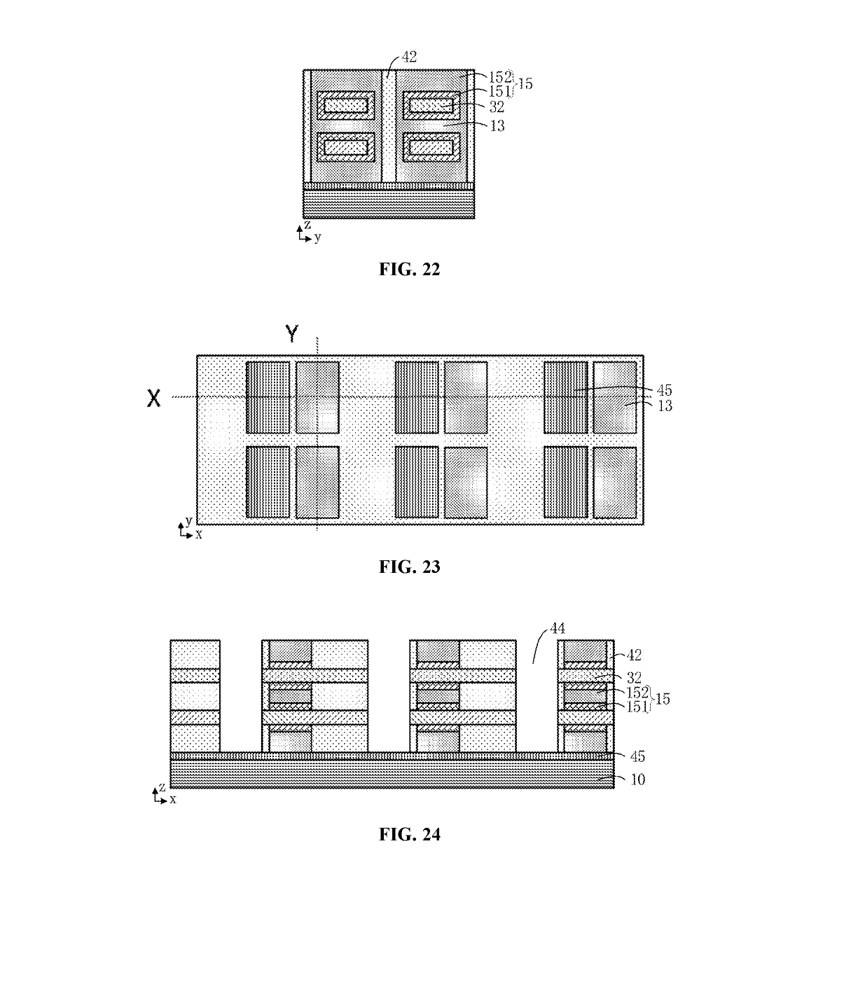

Referring to FIG. 20 to FIG. 22, in some embodiments, a gate-all-around dielectric layer 151 may be formed on an exposed surface of each horizontal semiconductor layer in the first through hole 43 by using at least one of an In-Situ Steam Generation (ISSG) process, an atomic layer deposition process, a plasma vapor deposition process, a Rapid Thermal Oxidation (RTO) process, or the like. The gate-all-around dielectric layers 151 surround the horizontal semiconductor layers exposed through the first through hole 43. The material of the gate-all-around dielectric layers 151 may be selected from silicon dioxide (SiO₂), silicon oxynitride (SiON), silicon nitride, aluminum oxide (Al₂O₃), aluminum oxynitride (AlON), and any combination thereof. The gate-all-around dielectric layers 151 may alternatively be made of a high k dielectric material (dielectric material with a dielectric constant greater than or equal to 3.9), a low k dielectric material (dielectric constant greater than or equal to 2.5 and less than 3.9), an ultralow k dielectric material (dielectric constant less than 2.5), a ferroelectric material, an anti-ferroelectric material, silicon carbide (SiC), or any combination thereof.

Referring to FIG. 20 to FIG. 22, in some embodiments, a gate-all-around electrode layer 152 or a write word line 13 may be formed in the first through hole 43 by using an atomic layer deposition process. The gate-all-around dielectric layers 151 and the gate-all-around electrode layer 152 are configured to jointly form the write transistors 15. A material of the gate-all-around electrode layer 152 or the write word line 13 is selected from Ti, TiN, Ta, TaN, Al, AlN, W, Cu, Pt, Mo, Ni, Ir, Ru, ITO, heavily doped polysilicon, and the like, and any combination thereof.

Referring to FIG. 23 to FIG. 24, in some embodiments, a second groove 44, through which a part of the substrate 10 is exposed, may be formed in the stack 30 by using an etching process, and the second groove 44 is configured to define a read transistor 16.

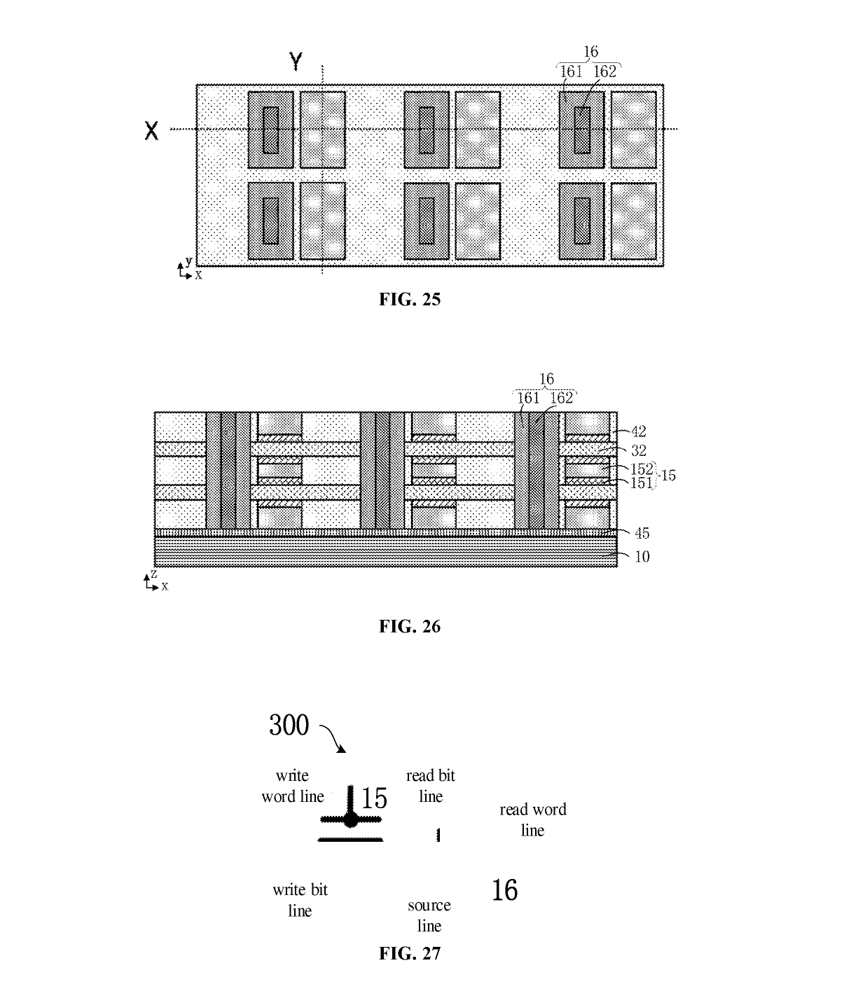

Referring to FIG. 25 to FIG. 26, in some embodiments, by using at least one of an In-Situ Steam Generation (ISSG) process, an atomic layer deposition process, a plasma vapor deposition process, a Rapid Thermal Oxidation (RTO) process, or the like, a vertical gate dielectric layer 161 is formed on an inner side wall of the second groove 44, and then, a vertical semiconductor layer 162 filling the second groove 44 is formed. A part of the semiconductor material layer 32, extending along the second direction, is configured to form a write bit line 14, a part of the semiconductor material layer 32, extending along the second direction, is configured to form a read word line 17, and the vertical gate dielectric layer 161 and the vertical semiconductor layer 162 are configured to jointly form the read transistor16, so as to obtain the write bit line 14, the write transistor 15, the read transistor 16, and the read word line 17 which are sequentially arranged along the first direction. A part of the semiconductor material layer 32, extending along the first direction, is configured to form the horizontal semiconductor layer 20. The first direction and the second direction intersect. A material of the vertical semiconductor layer 162 may be selected from indium gallium zinc oxide, indium zinc oxide, transition metal, transition metal oxide, and any combination thereof. It should be noted that the vertical semiconductor layer 162 may be composed of a single film or multiple composite films, and a material of the composite film may be selected from Si, ZnO, Ga₂O₃, In₂O₃, SnO₂, IGO, IZO, AZO, ITO, IGZO, IAZO, ITZO, and any combination thereof.

Further, with reference to FIG. 7 to FIG. 26, the stack 30 is formed on the substrate 10, the stack 30 including the sacrificial layers 31 and the semiconductor material layers 32 which are sequentially and alternately stacked in the direction away from the substrate 10. Multiple first grooves 41 are formed in the stack 30, these first grooves are arranged in an array with the first direction as the row direction and the second direction as the column direction, and a part of the substrate 10 is exposed through each first groove; in this way, parameters such as a shape, a size, and a position of each memory cell 100 in a subsequently manufactured array of memory cells 100 are preliminarily defined. The first through hole 43, through which a part of the substrate 10 and a part of the semiconductor material layers 32 are exposed, is formed in the stack 30, and the first through hole 43 is configured to define the write transistors 15, thereby defining parameters such as a shape, a size, and a position of the write transistor 15 of each memory cell 100 in the subsequently manufactured array of memory cells 100. The write transistor 15 surrounding a part of the semiconductor material layer 32 is formed in each semiconductor material layer 32 through the first through hole 43, and then, the write word line 13 filling the first through hole 43 is formed, thereby simultaneously manufacturing the shared write word line 13 of the memory cells 100 adjacent along a direction perpendicular to the substrate 10 in the same process step. The second groove 44, through which a part of the substrate 10 is exposed, is formed in the stack 30. The second groove 44 is configured to define the read transistor 16, thereby defining parameters such as a shape, a size, and a position of the read transistor 16 of each memory cell 100 in the subsequently manufactured array of memory cells 100. The vertical gate dielectric layer 161 is formed on the inner side wall of the second groove 44, the vertical semiconductor layer 162 filling the second groove 44 is then formed, a part of the semiconductor material layer 32 extending along the second direction is configured to form the write bit line 14, a part of the semiconductor material layer 32 extending along the second direction is configured to form the read word line 17, and the vertical gate dielectric layer 161 and the vertical semiconductor layer 162 are configured to jointly form the read transistor 16. Hence, the write bit line 14, the write transistor 15, the read transistor 16, and the read word line 17 which are sequentially arranged along the first direction are obtained. An area occupied by capacitors is relatively reduced, thereby reducing an area overhead of a single layer of memory cells 100; in addition, a volume of a manufactured product is reduced without any decrease in memory capacity.

In some embodiments, a material of the read bit line 12 can be selected from copper, tungsten, aluminum, a copper alloy, and any combination thereof.

In some embodiments, a material of the source line 11 can be selected from conductive metal, metal silicide, doped polysilicon, and the like, and any combination thereof.

In some embodiments, a material of the write bit line 14 can be selected from copper, tungsten, aluminum, a copper alloy, and any combination thereof.

Further, with reference to FIG. 8 to FIG. 26, in some embodiments, an etch stop layer 45 is provided between the substrate 10 and the stack 30. With the arrangement of the etch stop layer 45, the stack 30 is etched to form at least one of the first grooves 41, the first through hole 43, or the second groove 44, so that unnecessary etch damage to the substrate 10 is avoided in the process of etching any one of the first grooves 41, the first through hole 43, and the second groove 44, thereby improving the yield, the performance, and the reliability of the manufactured product.

In some embodiments, a material of the etch stop layer 45 may include SiO2 or SiN.

Referring to FIG. 1 to FIG. 3 and FIG. 27, in some embodiments, there is provided a data read-write circuit 300, including a write transistor 15 and a read transistor 16. The write transistor 15 is configured as follows: a first end of the write transistor 15 is connected to a write bit line 14, and a control end of the write transistor 15 is connected to a write word line 13. The read transistor 16 is configured as follows: a first control end of the read transistor 16 is connected to a second end of the write transistor 15, a second control end of the read transistor 16 is connected to a read word line 17, a first end of the read transistor 16 is connected to a read bit line 12, and a second end of the read transistor 16 is connected to a source line 11. The read transistor 16 is a gate-all-around transistor with a vertical channel. The read transistor 16 includes a vertical gate dielectric layer 161, and a vertical semiconductor layer 162 extending along a direction perpendicular to a substrate 10. The vertical gate dielectric layer 161 surrounds an outer side wall of the vertical semiconductor layer 162. The vertical gate dielectric layer 161 is located between the vertical semiconductor layer 162 and a horizontal semiconductor layer 20. The second end of the write transistor 15 is connected to the first control end of the read transistor 16 to form a storage node, the second control end of the read transistor 16 is connected to the read word line 17, the first end of the read transistor 16 is connected to the read bit line 12, and the second end of the read transistor 16 is connected to the source line 11. With the above arrangement, data is written into the storage node through the write bit line 14 in a case that the write transistor 15 is controlled to be turned on through the write word line 13; and data is read from the storage node through the read bit line 12 in a case that the read transistor 16 is controlled to be turned on through the read word line 17. An area occupied by capacitors is relatively reduced, thereby reducing an area overhead of a single layer of memory cells 100, and reducing a volume of a manufactured product without any decrease in memory capacity.

With the data read-write circuit 300 according to the above embodiment, data is written to the storage node SN by supplying a write signal to the write bit line 14 in the case where the write word line 13 controls the write transistor 15 to be turned on; and in the case where the write transistor 15 is turned off, the read word line 17 controls an on-characteristic of the read transistor 16, and data is read out from an amplitude of an electric signal acquired by the read bit line 12. For example, if the on-characteristic of the read transistor 16 is relatively good, the amplitude of the electrical signal (e.g., voltage signal or current signal) obtained via the read bit line 12 is relatively large, and then it is determined that data "1" is read out; conversely, if the on-characteristic of the read transistor 16 is relatively poor, the amplitude of the electric signal acquired via the read bit line 12 is relatively small, and then it is determined that data "0" is read out. The storage data is written and read by using the two transistors instead of depending on any capacitor structure, so a space volume caused by the capacitor structure is avoided while the memory capacity in unit volume is ensured not decreased. Hence, the storage density of the memory cell is increased, and the performance and the reliability of the memory cell is improved.

In some embodiments, still referring to FIG. 27, the write transistor 15 and the read transistor 16 may be N-type transistors. Alternatively, the write transistor 15 and the read transistor 16 may be P-type transistors. The write transistor 15 and the read transistor 16 may be the same type of transistors or different types of transistors.

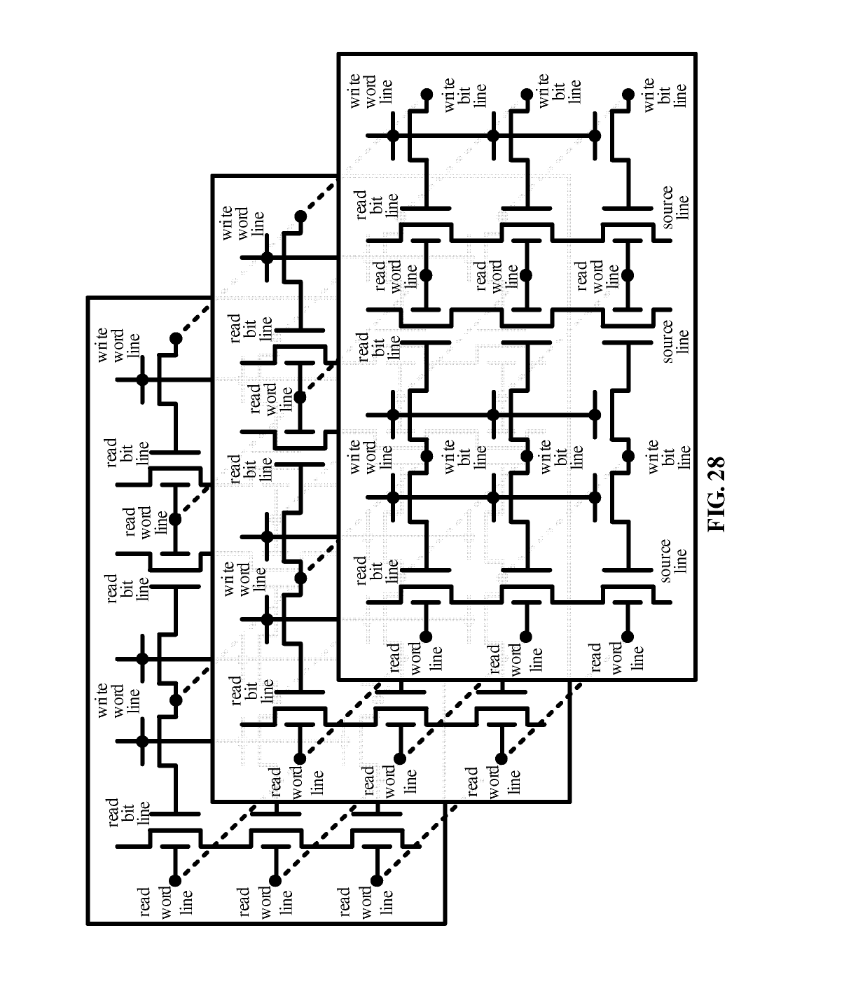

Referring to FIG. 28, in some embodiments, there is provided a three-dimensional data read-write circuit 400, including at least one layer of circuit array. Each of the at least one layer of circuit array includes multiple data read-write circuits according to any one of the foregoing embodiments, and these data read-write circuits are arranged in an array with a first direction as a row direction and a second direction as a column direction. Optionally, the three-dimensional data read-write circuit 400 includes multiple layers of circuit arrays, and the multiple layers of circuit arrays are arranged along a third direction. The data read-write circuits adjacent along the first direction share the read word line 17 and the write bit line 14. The data read-write circuits adjacent along the third direction share the write word line 13. The read transistor 16 is a gate-all-around transistor with a vertical channel. The read transistor 16 includes a vertical gate dielectric layer 161, and a vertical semiconductor layer 162 extending along a direction perpendicular to a substrate 10. The vertical gate dielectric layer 161 surrounds an outer side wall of the vertical semiconductor layer 162. The vertical gate dielectric layer 161 is located between the vertical semiconductor layer 162 and a horizontal semiconductor layer 20. Therefore, simultaneous photolithography for multiple layers of stacked memory cells 100 can be supported, and the process complexity and cost of product manufacturing are reduced. In addition, since one of two control gates is connected to one end of the write transistor 15 to form a storage node, and the other control gate is connected to the read word line 17 to read data, the area occupied by capacitors is relatively reduced, thereby reducing the area overhead of a single layer of memory cells 100, and reducing the volume of "2T0C" memory cells without any decrease in memory capacity.

It should be understood that, although the steps in FIG. 7 and the foregoing flow are shown in sequence as indicated by the arrows or the step sequence, the steps are not necessarily performed in sequence as indicated by the arrows. Unless explicitly stated herein, the steps are not limited to being performed in the exact order and may be performed in other orders. At least part of the steps in FIG. 7 and the foregoing flow may include multiple steps or multiple stages, which are not necessarily performed at the same moment, but may be performed at different moments, and the steps or the stages are not necessarily performed in sequence, but may be performed alternately with other steps or at least part of the steps or the stages in other steps.

The manufacturing orders of the write bit line, the write transistor, the storage node, the read bit line, the read transistor, and the source line in the foregoing embodiments can be exchanged randomly or combined mutually. Therefore, those skilled in the art can combine and/or exchange the manufacturing flows of any plurality of the write bit line, the write transistor, the storage node, the read bit line, the read transistor, and the source line without creative efforts, and all of them should belong to the protection scope of the embodiments of the present disclosure.

In some embodiments, there is provided an electronic device, including the memory according to any one of the embodiments of the present disclosure. The electronic device is, for example, but not limited to, a consumer electronic product, a home electronic product, a vehicle-mounted electronic product, a financial terminal product, or the like, of a suitable type. The consumer electronic product is, for example, a mobile phone, a tablet computer, a notebook computer, a desktop display, an all-in-one computer, or the like. The home electronic product is, for example, an intelligent door lock, a television, a refrigerator, a wearable device, or the like. The vehicle-mounted electronic product is, for example, a vehicle-mounted navigator, a vehicle-mounted DVD, or the like. The financial terminal product is, for example, an ATM machine, a terminal for self-service transaction, or the like.

It will be understood by those skilled in the art that all or part of the processes of the method according to the embodiments described above may be implemented by a computer program instructing related hardware, and the computer program may be stored in a non-transitory computer-readable storage medium, and when executed, may include the processes of the embodiments of the method described above. Any reference to memories, databases or other media used in the embodiments of the present application can include at least one of a non-transitory memory and a transitory memory. The non-transitory memory may include a read-only memory (ROM), a magnetic tape, a floppy disk, a flash memory, an optical memory, a high-density embedded non-transitory memory, a resistive random access memory (ReRAM), a magneto-resistive random access memory (MRAM), a ferroelectric random access memory (FRAM), a phase change memory (PCM), a graphene memory, or the like. The transitory memory can include a random access memory (RAM), an external cache memory, or the like. The databases involved in the embodiments of the present application may include at least one of relational and non-relational databases. The non-relational database may include, but is not limited to, a block chain-based distributed database, or the like. The processors referred to in the embodiments of the present application may include, but are not limited to, general processors, central processors, graphics processors, digital signal processors, programmable logic units, data processing logic units based on quantum calculations, or the like. The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the specification.

It should be noted that the above-described embodiments are for illustrative purposes only and are not intended to limit the present disclosure.

In the present specification, the embodiments are described in a progressive manner, each embodiment focuses on differences from other embodiments, and mutual reference may be made for the same or similar parts between the embodiments.

The above-described embodiments are only several implementations of the present application, and the descriptions are relatively specific and detailed, but they should not be construed as limiting the scope of the present disclosure. It should be understood by those of ordinary skill in the art that various modifications and improvements can be made without departing from the concept of the present application, and all fall within the protection scope of the present application.

What is claimed is:

1. A memory cell, comprising: a source line, a read bit line, a write word line, a horizontal semiconductor layer extending along a first direction, and a write bit line, a write transistor, a read transistor, and a read word line which are located on the horizontal semiconductor layer and sequentially arranged along the first direction; wherein
the write bit line and the read word line both extend along a second direction intersecting the first direction;
the read transistor extends along a third direction which is perpendicular to both the first direction and the second direction, and penetrates through the horizontal semiconductor layer; the read transistor comprises a vertical gate dielectric layer and a vertical semiconductor layer that extends along the third direction, and the vertical gate dielectric layer is located between the vertical semiconductor layer and the horizontal semiconductor layer;
the write transistor extends along the first direction and surrounds a part of the horizontal semiconductor layer;
the horizontal semiconductor layer and the write word line are arranged along the second direction; and
the source line, the read transistor, and the read bit line are arranged along the third direction.

2. The memory cell according to claim 1, wherein the vertical gate dielectric layer extends along the third direction and circumferentially surrounds the vertical semiconductor layer.

3. The memory cell according to claim 1, wherein the write transistor comprises:
a gate-all-around dielectric layer extending along the first direction and circumferentially surrounding a part of the horizontal semiconductor layer; wherein the write word line extends along the third direction and is located on a side of the gate-all-around dielectric layer away from the horizontal semiconductor layer along the second direction;
a first source/drain contact region, located at the horizontal semiconductor layer between the write bit line and the gate-all-around dielectric layer; and
a second source/drain contact region, located at the horizontal semiconductor layer between the gate-all-around dielectric layer and the read transistor.

4. The memory cell according to claim 3, wherein the write transistor further comprises:
a gate-all-around electrode layer, which is located between the write word line and the gate-all-around dielectric layer and circumferentially surrounds the gate-all-around dielectric layer.

5. The memory cell according to claim 1, wherein the read transistor comprises:
a first source/drain contact region, located at the vertical semiconductor layer between the horizontal semiconductor layer and the read bit line; and
a second source/drain contact region, located at the vertical semiconductor layer between the horizontal semiconductor layer and the source line.

6. A memory, comprising at least one layer of memory array;
wherein each of the at least one layer of memory array comprises a plurality of memory cells according to claim 1, the plurality of memory cells being arranged in an array with the first direction as a row direction and the second direction as a column direction;
the memory cells adjacent in the first direction share the read word line extending in the second direction, and share the write bit line extending in the second direction; and
the memory cells adjacent along the third direction share the write word line extending along the third direction.

7. The memory according to claim 6, wherein the memory comprises a plurality of layers of the memory arrays, and the plurality of layers of the memory arrays are arranged along the third direction.

8. A data read-write circuit, implemented based on the memory cell according to claim 1, comprising:
the write transistor, wherein a first end of the write transistor is configured to be connected to the write bit line, and a control end of the write transistor is configured to be connected to the write word line; and
the read transistor, wherein a first control end of the read transistor is configured to be connected to a second end of the write transistor, a second control end of the read transistor is configured to be connected to the read word line, a first end of the read transistor is configured to be connected to the read bit line, and a second end of the read transistor is configured to be connected to the source line.

9. A three-dimensional data read-write circuit, comprising at least one layer of circuit array;
wherein each of the at least one layer of circuit array comprises a plurality of data read-write circuits according to claim 8, the plurality of data read-write circuits being arranged in an array with the first direction as a row direction and the second direction as a column direction;
the data read-write circuits adjacent along the first direction share the read word line and the write bit line; and
the data read-write circuits adjacent along the third direction share the write word line.

10. The three-dimensional data read-write circuit according to claim 9, wherein the three-dimensional data read-write circuit comprises a plurality of layers of the circuit arrays, and the plurality of layers of the circuit arrays are arranged along the third direction.

11. A memory manufacturing method, comprising:
providing a substrate, wherein the substrate is provided thereon with a stack, the stack comprises sacrificial layers and semiconductor material layers which are sequentially and alternately stacked along a direction away from the substrate, and a plurality of first grooves are arranged in the stack, the plurality of first grooves being arranged in an array with a first direction as a row direction and a second direction as a column direction, wherein a part of the substrate is exposed through each of the plurality of first grooves;
forming an isolation layer which fills the plurality of first grooves and covers a top surface of a top semiconductor material layer of the stack;
forming a first through hole in the stack, wherein a part of the substrate and a part of the semiconductor material layers are exposed through the first through hole, and the first through hole is configured to define a write transistor;
forming the write transistor surrounding a part of the semiconductor material layer in each semiconductor material layer through the first through hole, and then forming a write word line filling the first through hole;
forming a second groove in the stack, wherein a part of the substrate is exposed through the second groove, and the second groove is configured to define a read transistor; and
forming a vertical gate dielectric layer on an inner side wall of the second groove, and then forming a vertical semiconductor layer filling the second groove; wherein a part of the semiconductor material layer, extending along the second direction, is configured to form a write bit line, a part of the semiconductor material layer, extending along the second direction, is configured to form a read word line, and the vertical gate dielectric layer and the vertical semiconductor layer are configured to jointly form the read transistor, so as to obtain the write bit line, the write transistor, the read transistor, and the read word line which are sequentially arranged along the first direction; wherein a part of the semiconductor material layer, extending along the first direction, is configured to form a horizontal semiconductor layer; and wherein the first direction intersect with the second direction.

12. The memory manufacturing method according to claim 11, wherein an etch stop layer is provided between the substrate and the stack; and
the stack is etched based on the etch stop layer, to form at least one of the first grooves, the first through hole, or the second groove.
